(19) United States
(12) Patent Application Publication
(10) Pub. No.: US 2026/0115806 A1
(43) Pub. Date: Apr. 30, 2026

(54) CUTTING TOOLS HAVING MULTILAYER COATINGS

(71) Applicant: KENNAMETAL INC., Latrobe, PA (US)

(72) Inventors: Zhenyu Liu, Latrobe, PA (US); Debangshu Banerjee, Latrobe, PA (US)

(21) Appl. No.: 18/930,480

(22) Filed: Oct. 29, 2024

(51) Int. Cl. B23B 27/14; C23C 16/30; C23C 16/40

(52) U.S. Cl. CPC B23B 27/148; C23C 16/303; C23C 16/403; B23B 2224/04; B23B 2224/32; B23B 2224/36

(57) ABSTRACT

In one aspect, cutting tools are described herein comprising wear resistant coatings employing multilayer architectures in conjunction with a highly textured alumina layer for resisting various degradative mechanisms, including cracking and/or flaking.

### FIELD

The present invention relates to refractory coatings and, in particular, to multilayer refractory coatings deposited by chemical vapor deposition (CVD) for cutting tool and/or metal removal applications.

### BACKGROUND

Cutting tools, including cemented carbide cutting tools, have been used in both coated and uncoated conditions for machining various metals and alloys. In order to increase cutting tool wear resistance, performance and lifetime, one or more layers of refractory material have been applied to cutting tool surfaces. TiC, TiCN, TiN and/or Al₂O₃, for example, have been applied to cemented carbide substrates by CVD and by physical vapor deposition (PVD). While effective in inhibiting wear and extending tool lifetime in a variety of applications, refractory coatings based on single or multi-layer constructions of the foregoing refractory materials have increasingly reached their performance limits, thereby calling for the development of new coating architectures for cutting tools.

### SUMMARY

In one aspect, cutting tools are described herein comprising wear resistant coatings employing multilayer architectures in conjunction with a highly textured alumina layer. In some embodiments, a coated cutting tool comprises a substrate, and a coating deposited by chemical vapor deposition (CVD) on the substrate, the coating comprising a layer of α-Al₂O₃ terminating at a multilayer structure above the α-Al₂O₃ layer, the multilayer structure comprising a base of metal nitride, metal carbonitride, metal oxycarbonitride, or combinations thereof. An outer layer of metal oxide or metal oxynitride is positioned over the base, wherein the base has a thickness of 0.1 μm or less, and the layer of α-Al₂O₃ has a texture coefficient of at least 7.0 for the (006) growth direction, the texture coefficient defined as:

$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$

where
I(hkl)=measured intensity of the (hkl) reflection
Iₒ(hkl)=standard intensity of the (hkl) reflection according to International Center for
Diffraction Data (ICDD) card 43-1484
n=number of reflections (8) used in the TC calculation
(hkl) reflections used in the TC calculation are:
(012), (104), (110), (006), (113), (202), (024) and (116).

In some embodiments, the outer layer has a thickness of 0.2 μm to 3 μm. Moreover, the metal oxide or metal oxynitride of the outer layer can comprise or more metals selected from the group consisting of aluminum and Groups IV-VI of the Periodic Table. In some embodiments, the base comprises titanium nitride or titanium carbonitride or titanium oxycarbonitride or combinations thereof.

These and other embodiments are further described in the following detailed description.

### BRIEF DESCRIPTION OF THE DRAWINGS

FIG. 1 illustrates a schematic cross-section of a coated cutting tool according to some embodiments described herein.

### DETAILED DESCRIPTION

Embodiments described herein can be understood more readily by reference to the following detailed description and examples and their previous and following descriptions. Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

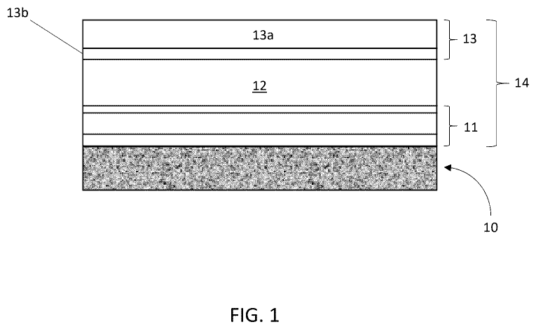

In one aspect, cutting tools are described herein comprising wear resistant coatings employing multilayer architectures in conjunction with a highly textured alumina layer for resisting various degradative mechanisms, including cracking and/or flaking. Accordingly, cutting tools having such refractory coatings are suitable for high wear and/or abrasion applications, such as metal cutting operations. FIG. 1 illustrates a schematic cross-section of a coated cutting tool according to some embodiments described herein. As illustrated in FIG. 1, the coated cutting tool comprises a substrate 10 and a CVD coating 14 adhered to the substrate 10. The coating 15 comprises a layer of α-Al₂O₃12 terminating at a multilayer structure 13 above the α-Al₂O₃ layer 12. The multilayer structure 13 comprises a base 13b of metal nitride, metal carbonitride, metal oxycarbonitride, or combinations thereof. An outer layer 13a of metal oxide or metal oxynitride is positioned over the base layer, wherein the base has a thickness of 0.1 μm or less. Intermediate layers 11 described herein are positioned between the α-Al₂O₃ layer 12 and the substrate 10. An outermost layer (not shown) may be deposited over the outer layer 13a, in some embodiments.

Turning now to specific components, a coated article comprises a substrate. A coated article can comprise any substrate not inconsistent with the objectives of the present invention. For example, a substrate can be a cutting tool or tooling used in wear applications. Cutting tools include, but are not limited to, cutting inserts (indexable and non-indexable), end mills, drills, and other round tools. Indexable cutting inserts can have any desired ANSI standard geometry for milling or turning applications. Substrates of coated articles described herein can be formed of cemented carbide, carbide, ceramic, cermet, steel or other alloy. A cemented carbide substrate, in some embodiments, comprises tungsten carbide (WC). WC can be present in a cutting tool substrate in an amount of at least about 80 weight percent or in an amount of at least about 85 weight percent. Additionally, metallic binder of cemented carbide can comprise cobalt or cobalt alloy. Cobalt, for example, can be present in a cemented carbide substrate in an amount ranging from 1 weight percent to 15 weight percent. In some embodiments, cobalt is present in a cemented carbide substrate in an amount ranging from 5-12 weight percent or from 6-10 weight percent. Further, a cemented carbide substrate may exhibit a zone of binder enrichment beginning at and extending inwardly from the surface of the substrate.

Cemented carbide substrates can also comprise one or more additives such as, for example, one or more of the following elements and/or their compounds: titanium, niobium, vanadium, tantalum, chromium, zirconium and/or hafnium. In some embodiments, titanium, niobium, vanadium, tantalum, chromium, zirconium and/or hafnium form solid solution carbides with WC of the substrate. In such embodiments, the substrate can comprise one or more solid solution carbides in an amount ranging from 0.1-7 weight percent. Additionally, a cemented carbide substrate can comprise nitrogen.

As described above, the CVD coating adhered to the substrate comprise a layer of α-Al₂O₃ terminating at a multilayer structure above the α-Al₂O₃ layer. The layer of α-Al₂O₃ has a texture coefficient of at least 7.0 for the (006) growth direction, the texture coefficient defined as:

$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$

where
I(hkl)=measured intensity of the (hkl) reflection
Iₒ(hkl)=standard intensity of the (hkl) reflection according to International Center for
Diffraction Data (ICDD) card 43-1484
n=number of reflections (8) used in the TC calculation
(hkl) reflections used in the TC calculation are:
(012), (104), (110), (006), (113), (202), (024) and (116).
   In some embodiments, the α-Al₂O₃ layer has a texture coefficient for the (006) growth direction of 7.5-7.9 or 7.6-7.9.

XRD peak data for calculations of the texture coefficients (TC) for the α-Al₂O₃ layer are measured on the as-coated top rake face of the cutting tool, such as a cutting insert, using a Bragg focusing diffractometer.

### Incidence Optics Included:

Long fine focus X-ray tube operating at 45 KV and 40 MA.
Variable divergence optic operating in automatic mode to insure constant irradiated sample volume throughout the analysis.
Fixed antiscatter slit

### Receiving Optics Included:

Variable Antiscatter slit operating in automatic mode to match the automatic divergence slit
Multistrip solid state detector operating in scanning mode.

Scan parameters (speed and count time) are selected to insure a minimum of ten data steps across the peak full width at half max (FWHM) and approximately 10,000 total counts on the most intense peak. Collected data is first converted from variable mode to fixed mode usable for analysis. This conversion is completed using the formula:

$${I}_{FIX} ( θ , a ) = {I}_{ADS} ( θ , L ) \times ( \frac{R sin ( a / 2 )}{L} ) \times ( \frac{1}{sin ( θ + a / 2 )} + \frac{1}{sin ( θ - a / 2 )} )$$

where α=the divergence angle and L=the irradiated length on the sample
The corrected intensity is analyzed using peak finding software to identify the peak position of all peaks in the collected data. The peaks are then refined using a profile function to precisely identify the peak position and peak height. This peak data is used for the alumina texture coefficient analysis. Due to the complexity of the CVD coating architecture, a thickness correction for the peak intensity was not applied.

Grains of the polycrystalline α-Al₂O₃ layer, in some embodiments, can exhibit a columnar morphology with the long axis normal or substantially normal to the substrate. The columnar grains, in some embodiments, can exhibit an average grain width less than 5 μm. Average grain width, in some embodiments, is less than 3 μm, such as 0.5 μm to 2.5 μm. In some embodiments, average grain width is 0.5-4.5 μm or 1-3 μm. Average grain width is an average of the width of 20 consecutive grains of the polycrystalline α-Al₂O₃ layer measured on the polished cross-section of the polycrystalline α-Al₂O₃ layer using band contrast EBSD imaging. Alumina grain width is determined by using the caliper function on the EBSD band contrast maps in the data collection software. Measurements are taken from approximately 20 adjacent grains in the center of the coating layer. The measurements from the caliper function are based on the SEM magnification and internal calibrations in the software.

The α-Al₂O₃ layer can have any desired thickness consistent with the technical objectives described herein. In some embodiments, the α-Al₂O₃ layer has a thickness of 2 μm to 20 μm, 2 μm to 6 μm, or 4 μm to 10 μm.

Further, the α-Al₂O₃ layer can exhibit low residual tensile stress in the as-deposited state. In some embodiments, the alumina phase has a residual tensile stress of 100-500 MPa or 20-400 MPa in the as-deposited state. Residual stress of the α-Al₂O₃ layer can be determined using the Chi tilt Sin²ψ method with reference to the (116) reflection. For the alumina phase analysis, Poisson's Ratio (ν) was set to 0.19, and the clastic modulus (E in GPa) was determined to be 415 from analysis of a single phase α-alumina coating by nanoindentation hardness.

The α-Al₂O₃ layer can be deposited directly on the substrate surface. Alternatively, a coating described herein can further comprise one or more inner layers between the α-Al₂O₃ layer and the substrate. Inner layer(s), in some embodiments, comprise one or more metallic elements selected from the group consisting of aluminum and metallic elements of Groups IVB, VB and VIB of the Periodic Table and one or more non-metallic elements selected from Groups IIIA, IVA, VA and VIA of the Periodic Table. In some embodiments, one or more inner layers between the substrate and multiphase refractory layer comprise a carbide, nitride, carbonitride, oxycarbonitride, oxide or boride of one or more metallic elements selected from the group consisting of aluminum and metallic elements of Groups IVB, VB and VIB of the Periodic Table.

For example, one or more inner layers are selected from the group consisting of titanium nitride, titanium carbonitride, titanium oxycarbonitride, titanium carbide, zirconium nitride, zirconium carbonitride, hafnium nitride, hafnium carbonitride, TiAlₓSi_{y}CᵥN, and aluminum oxynitride. Further, a layer of titanium oxycarbonitride can be employed as a bonding layer between the α-Al₂O₃ layer and inner layers of the coating. Inner layer(s) of the coating can have any thickness not inconsistent with the objectives of the present invention. In some embodiments, a single inner layer can have a thickness of at least 1.5 μm. Alternatively, a plurality of inner layers can collectively achieve thickness of at least 1.5 μm.

The grains of the α-Al₂O₃ layer terminate in a multilayer structure comprising a base of metal nitride, metal carbonitride, metal oxycarbonitride, or combinations thereof, and an outer layer of metal oxide or metal oxynitride over the base, wherein the base has a thickness of 0.1 μm or less. The base, in some embodiments, has a thickness selected from Table 1.

TABLE 1
Base Thickness (μm)
0.005-0.1
0.005-0.05
0.005-0.03
0.01-0.1
0.01-0.05

In alternative embodiments, the base can have a thickness greater than 0.1 μm, including 0.2 μm to 2 μm.

The nitride, carbonitride, and/or oxycarbonitride of the base can comprise one or more metals selected from Groups IV-VI of the Periodic Table. For example, in some embodiments, the base layer is titanium nitride, titanium carbonitride, or titanium oxycarbonitride. In other embodiments, the base can comprise a nitride, carbonitride, and/or oxycarbonitride of zirconium or chromium. The base can be a single layer having a thickness described herein, or the base can be multiple layers. The multiple layers can have differing compositions in some embodiments, when multiple layers are present, individual layer thicknesses are such that the sum of the individual layers yields a thickness value recited herein for the base, such as the values listed in Table 1.

The multilayer structure terminating grain growth of the α-Al₂O₃ layer additionally comprises an outer layer of metal oxide or metal oxynitride over the base layer. In some embodiments, the metal oxide or metal oxynitride comprises one or more metals selected from the group consisting of aluminum and Groups IV-VI of the Periodic Table. For example, the metal can be aluminum for the production of alumina, AlON, or mixtures thereof in the outer layer. In some embodiments, wherein Al₂O₃ is present in the outer layer, the Al₂O₃ can be α-Al₂O₃, κ-Al₂O₃, or mixtures thereof. In other embodiments, the outer layer can comprise zirconia (ZrO₂). Additionally, in some embodiments, the metal oxide and/or metal oxynitride of the outer layer is doped with a metal selected from Groups IV-VI of the Periodic Table. For example, the outer layer of the multilayer structure can comprise alumina doped with zirconium. In some embodiments, metal dopant can be dispersed throughout the oxide or oxynitride layer. Alternatively, the metal dopant can localize at grain boundaries within the oxide or oxynitride layer. In further embodiments, the metal oxide or metal oxide nitride of the outer layer can comprise a dispersed metal oxide phase, the dispersed metal oxide phase comprising one more metals selected from Groups IV-VI of the Periodic Table. The outer layer of metal oxide or metal oxynitride can have any desired thickness consistent with the technical objective described herein. In some embodiments, the outer layer has a thickness of 0.05 μm to 3 μm.

Coatings described herein, in some embodiments, further comprise an outermost layer disposed over the outer layer of the multilayer structure. The outermost layer can comprise a nitride, carbonitride, and/or oxynitride of one or more metals selected from Groups IV-VI of the Periodic Table. The outermost layer can be a single layer or multiple layers. In some embodiments, for example, the outermost layer comprises one or more of TIN, TiCN, TiOCN, or ZrCN. The outermost layer can have a thickness of 0.2 μm to 3 μm, in some embodiments.

Coatings described herein can be subjected to post-coat treatments. Coatings, for example, can be blasted with various wet and/or dry particle compositions. Post coat blasting can be administered in any desired manner. In some embodiments, post coat blasting comprises shot blasting or pressure blasting. Pressure blasting can be administered in a variety of forms including compressed air blasting, wet compressed air blasting, pressurized liquid blasting, wet blasting and steam blasting. Wet blasting, for example, is accomplished using a slurry of inorganic and/or ceramic particles, such as alumina, and water. The particle slurry can be pneumatically projected at a surface of the coated cutting tool body to impinge on the surface of the coating. The inorganic and/or ceramic particles can generally range in size between about 20 μm and about 100 μm.

In some embodiments, the multilayer structure and any outermost layer can be removed by post-coat treatment to expose the underlying α-Al₂O₃ layer. Removal of the multilayer structure and any outermost layer can be conducted on the rake or flank faces of the cutting tool. In some embodiments, such removal is conducted on both the rake and flank faces. Removal of the multilayer structure can impart a compressive residual stress condition to the underlying α-Al₂O₃ layer. In some embodiments, the multilayer layer structure is removed on the rake face(s) of the cutting tool to impart a compressive residual stress condition to the underlying α-Al₂O₃ layer of the rake. The compressive stress condition can range from −100 MPa to −500 MPa, in some embodiments. The multilayer structure is not removed from the adjacent rake face, whereby the underlying α-Al₂O₃ layer exhibits a tensile residual stress condition, as described above.

These and other embodiments are further illustrated in the following non-limiting examples.

### Example 1—Coated Cutting Tools

Sintered cemented carbide cutting inserts of geometry CNMG432RN were provided having the composition of Table 2.

TABLE 2
Sintered Cemented Carbide Substrate Composition

| Component | Weight Percent |
|---|---|
| Cobalt | 6.9-7.1 |
| Group IV-VI Carbides | 5.05-6.25 |
| WC | Balance |

The sintered cemented carbide cutting inserts were provided a multilayer CVD coating having the composition and architecture provided in Table 3.

TABLE 3
CVD Coating Architecture

| Layer | Thickness (μm) |
|---|---|
| TiN* | 0.4 |
| MT-TiCN | 8.2 |
| TiOₓC_{y}N_{z} | 0.8 |
| α-Al₂O₃ | 7.8 |
| TiN Base | 0.04 |
| Al₂O₃ Outer layer | 0.5 |

*Layer adjacent to substrate

The coating was deposited in a Bernex CVD furnace commercially available from Ionbond IHI Group. The coating was deposited according to the parameters of Tables 4 and 5.

TABLE 4
Deposition of Intermediate Layers and High Texture α-Al₂O₃

| | H₂ | N₂ | TiCl₄ | CH₃CN | CH₄ | AlCl₃ | CO₂ | CO | HCl | H₂S | NH₃ |
|---|---|---|---|---|---|---|---|---|---|---|---|
| Process Step | vol. % | vol. % | vol. % | vol. % | vol. % | vol. % | vol. % | vol. % | vol. % | vol. % | vol. % |
| TiN | Bal. | 18.40 | 0.95 | — | — | — | — | — | — | — | — |
| MT-TiCN | Bal. | 27.8 | 1.31 | 0.001 | — | — | — | — | 1.40 | — | — |
| HT-TiCN | Bal. | 16.69 | 0.76 | — | 3.70 | — | — | — | — | — | — |
| TiOCN | Bal. | 17.50 | 1.08 | — | 2.52 | — | — | 1.10 | 1.10 | — | — |
| Al₂O₃ | Bal. | — | — | — | — | 4.84 | 2.42 | 0.45 | 3.00 | — | — |
| Nucleation | | | | | | | | | | | |
| High Texture | Bal. | — | — | — | — | 4.84 | 2.42 | 0.48 | 3.00 | 0.50 | — |
| Al₂O₃ | | | | | | | | | | | |

TABLE 5
Deposition of Multilayer Structure

| | | Al₂O₃ | Al₂O₃ |
|---|---|---|---|
| Process parameters | TiN Base Layer | Nucleation | Outer Layer |
| Temperature (° C.) | 750-1000 | 850-1050 | 850-1050 |
| Time (min) | 2-15 | 5-20 | 30-80 |
| Pressure (mbar) | 60-90 | 65-85 | 65-85 |
| H₂ (vol. %) | Balance | Balance | Balance |
| N₂ (vol. %) | 30 | 3.5 | — |
| TiCl₄ (vol. %) | 0.01 | — | — |
| AlCl₃ (vol. %) | — | 2 | 2 |
| CO₂ (vol. %) | — | 4.25 | 4.25 |
| CO (vol. %) | — | 2.4 | 2.4 |
| HCl (vol. %) | — | 1.8 | 1.8 |
| H₂S (vol. %) | — | — | 0.4 |

Two of the inventive coated inserts were subjected to metal cutting testing relative to KCP25C comparative inserts of the same geometry commercially available from Kennametal Inc. The two inventive coated inserts exhibited texture coefficients for the (006) growth direction of the α-Al₂O₃ layer exceeding a value of 7.5.
Parameters of the turning tests for flank wear were:
Workpiece: 4340 Steel
Speed: 675 sfm
Feed Rate: 0.12 ipr
Depth of Cut: 0.1 doc
Coolant: flood
Parameters of the turning tests for crater wear were:
Workpiece: 1045 Steel
Speed: 1200 sfm
Feed Rate: 0.12 ipr
Depth of Cut: 0.08 doc
Coolant: flood
   The results of the continuous turning testing are provided in Table 6.

TABLE 6
Metal Cutting Results

| | Tool Life/Failure Mode | |
|---|---|---|
| Sample | Flank Wear (minutes) | Crater Wear (minutes) |
| Inventive Sample 1 | 11.1 | 14.4 |
| Inventive Sample 2 | 8.8 | 19.4 |
| KCP25C Comparative | 6.5 | 10.2 |

As provided in Table 6, the cutting inserts comprising the inventive coating described herein demonstrate significantly longer tool life relative to the comparative KCP25C.

### Example 2—Coated Cutting Tools

Sintered cemented carbide cutting inserts of Example 1 were provided a multilayer CVD coating having the composition and architecture provided in Table 7.

TABLE 7
CVD Coating Architecture

| Layer | Thickness (μm) |
|---|---|
| TiN* | 0.4 |
| MT-TiCN | 7.8 |
| TiOₓC_{y}N_{z} | 0.8 |
| α-Al₂O₃ | 8.0 |
| TiN Base | 0.04 |
| Zr-doped Al₂O₃ Outer layer | 0.5 |

*Layer adjacent to substrate

The coating was deposited in a Bernex CVD furnace according to the parameters of Table 4 in Example 1 and Table 8 below.

TABLE 8
Deposition of Multilayer Structure

| | | Al₂O₃ | Zr—Al₂O₃ |
|---|---|---|---|
| Process parameters | TiN Barrier Layer | Nucleation | Growth |
| Temperature (° C.) | 750-1000 | 850-1050 | 850-1050 |
| Time (min) | 2-15 | 5-20 | 30-80 |
| Pressure (mbar) | 60-90 | 65-85 | 65-85 |
| H₂ (vol. %) | Balance | Balance | Balance |
| N₂ (vol. %) | 30 | 3.5 | — |
| TiCl₄ (vol. %) | 0.01 | — | — |
| AlCl₃ (vol. %) | — | 2 | 2 |
| ZrCl₄ (vol. %) | — | — | 1.3 |
| CO₂ (vol. %) | — | 4.25 | 4.25 |
| CO (vol. %) | — | 2.4 | 2.4 |
| HCl (vol. %) | — | 1.8 | 1.6 |
| H₂S (vol. %) | — | — | 0.4 |

Two of the inventive coated inserts were subjected to metal cutting testing relative to KCP25C comparative inserts of the same geometry commercially available from Kennametal Inc. The two inventive coated inserts exhibited texture coefficients for the (006) growth direction of the α-Al₂O₃ layer exceeding a value of 7.5. Parameters of the metal cutting tests were the same as in Example 1.
The results of the continuous turning testing are provided in Table 9.

TABLE 9
Metal Cutting Results

| | Tool Life/Failure Mode | |
|---|---|---|
| Sample | Flank Wear (minutes) | Crater Wear (minutes) |
| Inventive Sample 1 | 15.9 | 21.7 |
| Inventive Sample 2 | 12.0 | 23.3 |
| KCP25C Comparative | 6.5 | 10.2 |

As provided in Table 9, the cutting inserts comprising the inventive coating described herein demonstrate significantly longer tool life relative to the comparative KCP25C.

### Example 3—Coated Cutting Tools

Sintered cemented carbide cutting inserts of Example 1 were provided a multilayer CVD coating having the composition and architecture provided in Table 10.

TABLE 10
CVD Coating Architecture

| Layer | Thickness (μm) |
|---|---|
| TiN* | 0.4 |
| MT-TiCN | 8.2 |
| TiOₓC_{y}N_{z} | 0.8 |
| α-Al₂O₃ | 8.0 |
| TiN Base | 0.04 |
| ZrO₂ Outer layer | 0.5 |

*Layer adjacent to substrate

The coating was deposited in a Bernex CVD furnace according to the parameters of Table 4 in Example 1 and Table 11 below.

TABLE 11
Deposition of Multilayer Structure

| | | Al₂O₃ | ZrO₂ |
|---|---|---|---|
| Process parameters | TiN Barrier Layer | Nucleation | Growth |
| Temperature (° C.) | 750-1000 | 850-1050 | 850-1050 |
| Time (min) | 2-15 | 5-20 | 30-80 |
| Pressure (mbar) | 60-90 | 65-85 | 65-85 |
| H₂ (vol. %) | Balance | Balance | Balance |
| N₂ (vol. %) | 30 | 3.5 | — |
| TiCl₄ (vol. %) | 0.01 | — | — |
| AlCl₃ (vol. %) | — | 2 | 2 |
| ZrCl₄ (vol. %) | — | — | 1.3 |
| CO₂ (vol. %) | — | 4.25 | 4.25 |
| CO (vol. %) | — | 2.4 | 2.4 |
| HCl (vol. %) | — | 1.8 | 1.6 |
| H₂S (vol. %) | — | — | 0.4 |

Two of the coated inserts were subjected to metal cutting testing relative to KCP25C inserts of the same geometry commercially available from Kennametal Inc. The two coated inserts exhibited texture coefficients for the (006) growth direction of the α-Al₂O₃ layer exceeding a value of 7.5. Parameters of the metal cutting tests were the same as in Example 1.
The results of the continuous turning testing are provided in Table 12.

TABLE 12
Metal Cutting Results

| | Tool Life/Failure Mode | |
|---|---|---|
| Sample | Flank Wear (minutes) | Crater Wear (minutes) |
| Inventive Sample 1 | 14.0 | 22.0 |
| Inventive Sample 2 | 12.6 | 24.1 |
| KCP25C Comparative | 6.5 | 10.2 |

As provided in Table 11, the cutting inserts comprising the inventive coating described herein demonstrate significantly longer tool life relative to the comparative KCP25C.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. A coated cutting tool comprising:
a substrate; and
a coating deposited by chemical vapor deposition (CVD) on the substrate, the coating comprising a layer of α-Al₂O₃ terminating at a multilayer structure above the α-Al₂O₃ layer, the multilayer structure comprising a base of metal nitride, metal carbonitride, metal oxycarbonitride, or combinations thereof, and an outer layer of metal oxide or metal oxynitride over the base layer, wherein the base has a thickness of 0.1 μm or less, and the layer of α-Al₂O₃ has a texture coefficient of at least 7.0 for the (006) growth direction, the texture coefficient defined as:
$$TC ( hkl ) = \frac{I ( hkl )}{{I}_{o} ( hkl )} {\{ \frac{1}{n} \sum \frac{I ( hkl )}{{I}_{o} ( hkl )} \}}^{- 1}$$
where
I(hkl)=measured intensity of the (hkl) reflection
Iₒ(hkl)=standard intensity of the (hkl) reflection according to International Center for Diffraction Data (ICDD) card 43-1484
n=number of reflections (8) used in the TC calculation
(hkl) reflections used in the TC calculation are:
(012), (104), (110), (006), (113), (202), (024) and (116).

2. The coated cutting tool of claim 1, wherein the texture coefficient is 7.6 to 7.9.

3. The coated cutting tool of claim 1, wherein the outer layer has a thickness of 0.2 μm to 3 μm.

4. The coated cutting tool of claim 1, wherein the metal oxide or metal oxynitride comprises one or more metals selected from the group consisting of aluminum and Groups IV-VI of the Periodic Table.

5. The coated cutting tool of claim 1, wherein metal oxide or metal oxynitride is doped with a metal selected from Groups IV-VI of the Periodic Table.

6. The coated cutting tool of claim 5, wherein the metal oxide is Al₂O₃.

7. The coated cutting tool of claim 4, wherein the outer layer comprises Al₂O₃, AlON, or mixtures thereof.

8. The coated cutting tool of claim 4, wherein the outer layer comprises ZrO₂.

9. The coated cutting tool of claim 1, wherein the base thickness is from 0.005 μm to 0.05 μm.

10. The coated cutting tool of claim 1, wherein the coating further comprises one or more intermediate layers between the substrate and the α-Al₂O₃ layer.

11. The coated cutting tool of claim 1, wherein the α-Al₂O₃ layer comprises columnar grains terminating at the base.

12. The coated cutting tool of claim 1, wherein the multilayer structure further comprises an outermost layer over the outer layer.

13. The coated cutting tool of claim 12, wherein the outermost layer comprises at least one of a metal carbide, metal nitride, metal carbonitride, and metal oxycarbonitride.

14. The coated cutting tool of claim 13, wherein the metal of the metal carbide, metal nitride, metal carbonitride, or metal oxycarbonitride of the outermost layer is selected from Groups IV-VI of the Periodic Table.

15. The coated cutting tool of claim 13, wherein the outermost layer comprises TiCN and TiN.

16. The coated cutting tool of claim 14, wherein the metal of the outermost layer is chromium.

17. The coated cutting tool of claim 1, wherein the base comprises TiN, TiCN, TiOCN, or combinations thereof.

18. The coated cutting of claim 6, wherein the metal dopant is zirconium.

19. The coated cutting tool of claim 1, wherein the α-Al₂O₃ layer has a thickness of 2 μm to 20 μm.

20. The coated cutting tool of claim 1, wherein the substrate comprises cemented carbide.
